(19) United States
(12) Patent Application Publication
(10) Pub. No.: US 2016/0164254 A1
(43) Pub. Date: Jun. 9, 2016

(54) SURFACE EMITTING LASER AND OPTICAL COHERENCE TOMOGRAPHY APPARATUS

(71) Applicant: CANON KABUSHIKI KAISHA, Tokyo (JP)

(72) Inventor: Yasuhisa Inao, Tokyo (JP)

(21) Appl. No.: 14/904,016

(22) PCT Filed: Jul. 7, 2014
(86) PCT No.: PCT/JP2014/003577

§ 371 Date: Jan. 8, 2016

(30) Foreign Application Priority Data
Jul. 12, 2013 (JP) 2013-146953

(51) Int. Cl. H01S 5/06; G01B 9/02; H01S 3/106; H01S 5/183; H01S 3/105

(52) U.S. Cl. CPC H01S 5/0607; H01S 5/18363; H01S 3/105; H01S 3/1062; G01B 9/02091

(57) ABSTRACT

A surface emitting laser is provided which requires a smaller number of components, and which can reduce the cost.

A surface emitting laser includes a cavity constituted by a first reflecting mirror and a second reflecting mirror, and having a resonant wavelength that is changed by changing a cavity length with movement of the first reflecting mirror in a direction facing the second reflecting mirror. The surface emitting laser further includes an active layer arranged in the cavity and emitting light, a third reflecting mirror arranged on the opposite side of the active layer with respect to the second reflecting mirror, and a light receiving element arranged to receive light passing through the third reflecting mirror.

### TECHNICAL FIELD

The present invention relates to a surface emitting laser (vertical cavity surface emitting laser) and an optical coherence tomography apparatus including the surface emitting laser as a wavelength-swept light source.

### BACKGROUND ART

An Optical Coherence Tomography (OCT) apparatus is an apparatus capable of obtaining a tomographic image of a test object in a non-invasive manner using light based on the low-coherence interferometry. While the OCT apparatus is utilized in various fields, it is very useful in the medical field particularly for the reason that the tomographic image of the test object can be observed in a non-invasive manner and the burden on a patient can be reduced.

The use of the OCT apparatus has quickly become popular particularly in ophthalmologic care where observation from the outside is a main diagnostic approach.

OCT is primarily grouped into two methods called Time Domain OCT and Fourier Domain OCT (FD-OCT). Furthermore, as FD-OCT, there are two methods called Spectral Domain OCT (SD-OCT) and Swept Source OCT (SS-OCT).

In an SS-OCT apparatus, a light source having wavelength temporally changeable over a wide band is used, and the intensity of interference light between probe light and reference light is obtained at each wavelength. An interference fringe with respect to wavelength is subjected to the Fourier transform, and the position of a reflecting surface in the direction of depth on an optical axis is calculated, thus forming a tomographic image.

A device for monitoring a wavelength (optical frequency) of light output from the wavelength-variable light source is required in the SS-OCT apparatus to grasp the relationship between the intensity of an interference signal and the optical frequency at each time. This is because, in an FD-OCT apparatus, a tomographic image in the direction of depth axis is formed through the Fourier transform of the optical interference signal with respect to the optical frequency. In other words, the tomographic image cannot be obtained with the Fourier transform if there is no information indicating which optical frequency corresponds to the obtained interference signal.

In particular, sampling the interference signal at a uniform optical frequency interval is required in a process of the discrete Fourier transform. To create a trigger signal for the sampling at the uniform optical frequency interval, an optical frequency monitor called a k-clock, described in NPL 1, is employed in the SS-OCT apparatus.

Moreover, in NPL 1, a surface emitting laser in which a resonant frequency is changed by changing a resonator length (cavity length) with driving of a reflecting mirror is used as the wavelength-variable light source.

### CITATION LIST

### Non Patent Literature

[NPL 1] I. Grulkowski, J. J. Liu, B. Potsaid, V Jayaraman, C. D. Lu, J. Jiang, A. E. Cable, J. S. Duker, and J. G. Fujimoto, “Retinal, anterior segment and full eye imaging using ultrahigh speed swept source OCT with vertical-cavity surface emitting lasers.” Optics Express, vol. 3, 2012, pp. 1213-1229.
[NPL 2] R. Magnusson, S. S. Wang, and S. S. Wang, “New principle for optical filters.” Applied Physics Letters, vol. 61, 1992, p. 1022.
[NPL 3]Y. Zhou, M. C. Huang, and C. J. Chang-hasnain, “Tunable VCSEL with ultra-thin high contrast grating for high-speed tuning.” Optics Express, vol. 16, 2008, p. 14221

### SUMMARY OF INVENTION

### Technical Problem

However, the SS-OCT apparatus has the problem that a larger number of components are required and cost is increased.

More specifically, in any type of SS-OCT apparatus, a trigger to obtain a signal is generated by the optical frequency monitor using an interferometer, called the k-clock, for the sampling of the interference signal at the uniform optical frequency interval.

The k-clock is constituted, as illustrated in NPL 1, such that after branching light from a light source, the branched lights are caused to interfere with each other through optical fibers, lenses, and a multiplier, and an intensity signal of the interference light is converted to an electric signal by a light receiving element.

Thus, the k-clock requires many components and steps of assembling those components with high accuracy. The cost of the SS-OCT apparatus is thereby increased.

The present invention provides a surface emitting laser and an optical coherence tomography apparatus, which require a smaller number of components, and which can reduce the cost.

### Solution to Problem

According to the present invention, there is provided a surface emitting laser including a cavity constituted by a first reflecting mirror and a second reflecting mirror, and having a resonant wavelength that is changed by changing a cavity length with movement of the first reflecting mirror in a direction facing the second reflecting mirror, wherein the surface emitting laser further includes an active layer arranged in the cavity and emitting light, a third reflecting mirror arranged on the opposite side of the active layer with respect to the second reflecting mirror, and a light receiving element arranged to receive light passing through the third reflecting mirror.

According to the present invention, there is further provided an optical coherence tomography apparatus including a light source constituted by the above-described wavelength-variable surface emitting laser, a test-object optical path through which light from the light source is applied to a test object and reflected light from the test object is transferred, a reference-light optical path through which the light from the light source is transferred, an interference unit configured to interfere the reflected light transferred through the test-object optical path and the light transferred through the reference-light optical path with each other, an optical detection unit configured to detect interference light from the interference unit, and an arithmetic processing unit configured to obtain an interference signal in synchronism with a trigger signal output from the light source, and to provide a tomographic image of the test object.

Further features of the present invention will become apparent from the following description of exemplary embodiment with reference to the attached drawings.

### Advantageous Effects of Invention

With the present invention, the surface emitting laser and the optical coherence tomography apparatus are realized which require a smaller number of components, and which can reduce the cost.

### BRIEF DESCRIPTION OF DRAWINGS

FIG. 1 is a sectional view to explain an example of structure of a wavelength-variable surface emitting laser according to an embodiment of the present invention.

FIG. 2 is a graph to explain characteristics of a Fabry-Perot etalon structure in the embodiment of the present invention.

FIG. 3 is a sectional view to explain an example of structure of a wavelength-variable surface emitting laser according to Example 1 of the present invention.

FIG. 4 is a graph representing a threshold gain coefficient that changes depending on a reflectivity ratio between an upper reflecting mirror and an outer reflecting mirror in Example 1 of the present invention.

FIG. 5 is a block diagram to explain an example of structure of an SS-OCT apparatus according to Example 1 of the present invention.

FIG. 6 is a sectional view to explain an example of structure of a wavelength-variable surface emitting laser according to Example 2 of the present invention.

### DESCRIPTION OF EMBODIMENT

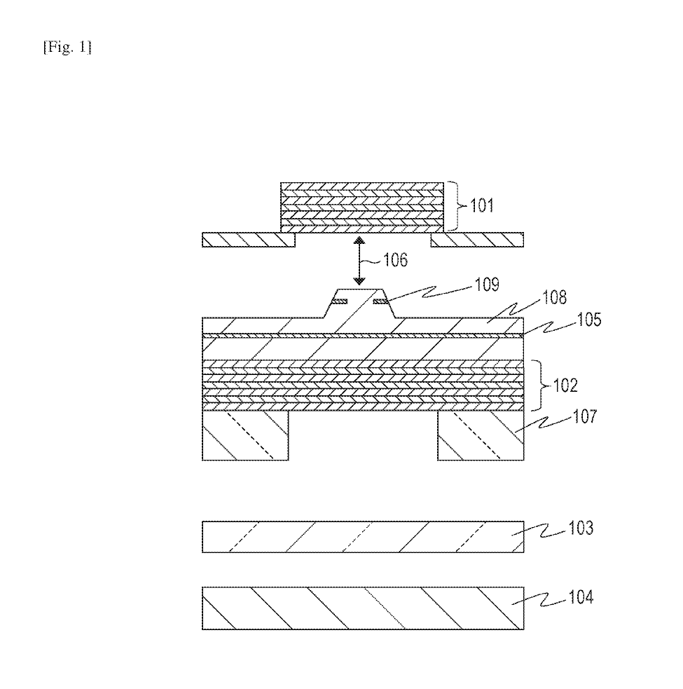

An example of structure of a wavelength-variable surface emitting laser according to an embodiment of the present invention will be described below with reference to FIG. 1.

The wavelength-variable surface emitting laser according to the embodiment of the present invention includes a cavity in which a pair of reflecting mirrors, i.e., a first reflecting mirror and a second reflecting mirror, are arranged to face each other. The first reflecting mirror is moved in the direction facing the second reflecting mirror to change a resonator length (cavity length), thereby changing a resonance wavelength.

In more detail, as illustrated in FIG. 1, an active layer 105 emitting light and a lower reflecting mirror (second reflecting mirror) 102, both formed on a substrate 107, are arranged at a position facing an upper reflecting mirror (first reflecting mirror) 101, which is movable in the direction normal to the substrate (i.e., in the up and down direction on the drawing sheet), with an air gap 106 interposed between both the reflecting mirrors. The substrate 107 supports the lower reflecting mirror 102, and it is bored in a portion corresponding to the active layer 105.

The active layer 105 is positioned within the cavity formed by the upper reflecting mirror 101 and the lower reflecting mirror 102 such that laser oscillation can be developed by amplifying light generated from the active layer 105. A spacer layer 108 serving to efficiently transport carriers (in the case of current injection) is formed on the active layer 105, and a current confinement structure 109 is formed in the protective layer 108. Carriers are injected from a pair of electrodes (not illustrated) that are positioned on both sides of the active layer 105. The active layer 105 emits light upon recombination of the carriers in the active layer.

The length of the cavity constituted by the upper reflecting mirror 101 and the lower reflecting mirror 102 is changed by driving the upper reflecting mirror 101. As a result, the resonant wavelength of the laser can be changed.

In the embodiment of the present invention, another reflecting mirror is further disposed in pair with the lower reflecting mirror 102.

More specifically, in the wavelength-variable surface emitting laser according to this embodiment, an outer reflecting mirror (third reflecting mirror) 103 is arranged on the side opposite to the active layer 105 with the lower reflecting mirror 102 interposed therebetween. Furthermore, a light receiving element 104 receives light having passed through the third reflecting mirror.

A Fabry-Perot etalon is formed by the lower reflecting mirror 102 and the outer reflecting mirror 103 of the above-described wavelength-variable surface emitting laser.

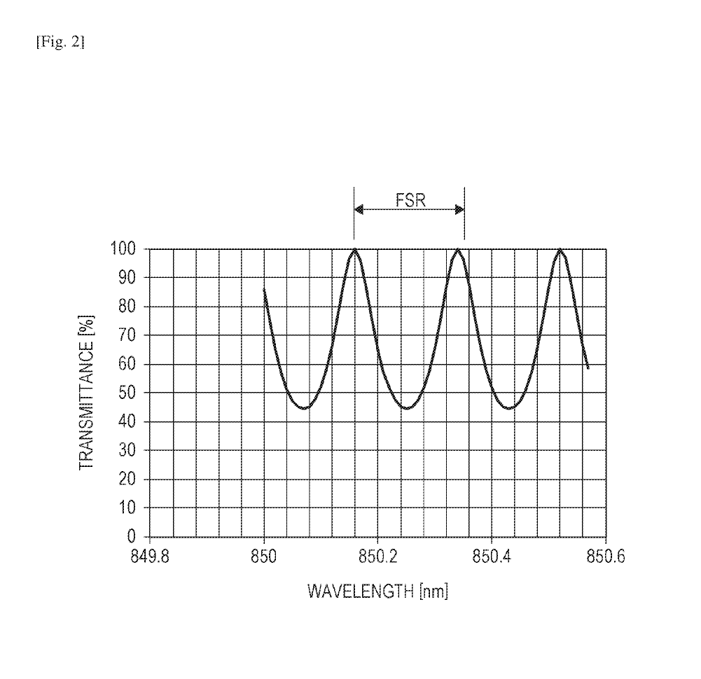

The Fabry-Perot etalon has such characteristics that, as illustrated in FIG. 2, transmittance varies at a certain period of optical frequency, called a Free Spectral Range (FSR) which is determined depending on a mirror interval.

The FSR is expressed by c/2L where c is the velocity of light, and L is an optical path length between reflecting mirrors constituting the Fabry-Perot etalon. The optical path length L is expressed by L=nd where n is the refractive index of a medium in the Fabry-Perot etalon, and d is a distance between the reflecting mirrors. When there are plural media in the Fabry-Perot etalon, the optical path length L between the reflecting mirrors constituting the Fabry-Perot etalon is expressed by a total sum of the products of the refractive indexes and the thicknesses of those media.

Therefore, when the upper reflecting mirror 101 of the wavelength-variable surface emitting laser is moved relative to the active layer 105 and the lower reflecting mirror 102 in the direction normal thereto, the resonator length (cavity length) is changed and hence the resonant wavelength is also changed. Thus, the intensity of light output from the Fabry-Perot etalon constituted by the lower reflecting mirror 102 and the outer reflecting mirror 103 (i.e., output from the side of the outer reflecting mirror 103 opposite to the second reflecting mirror 102) is modulated. Such modulation is generated in tune with the interval of the FSR.

Since the modulation of the light intensity is generated in tune with the interval of the FSR, which is constant on the axis of optical frequency, as described above, it can be utilized as the so-called k-clock signal to execute sampling at a uniform optical frequency interval.

For example, a peak of the intensity of the light output from the Fabry-Perot etalon side may be detected as the k-clock signal. Alternatively, a valley of the light intensity may be detected.

When the wavelength-variable surface emitting laser according to this embodiment is used as a light source of an optical coherence tomography apparatus, the above-mentioned Free Spectral Range (FSR) determined depending on the optical distance between the lower reflecting mirror 102 and the outer reflecting mirror 103 is desirably narrower than an optical frequency interval expressed by c/4x where x (m) is a predetermined depth image-capturing range in the optical coherence tomography apparatus, and c (m/s) is the velocity of light.

Furthermore, given that a predetermined depth axial image resolution in the optical coherence tomography apparatus is denoted by y and the velocity of light is denoted by c, the above-mentioned Free Spectral Range (FSR) is desirably wider than an optical frequency interval c/2Ny resulting from dividing an optical frequency range expressed by c/2y by the number N of data subjected to the Fourier transform.

The outer reflecting mirror 103 used here may be an interface between the substrate and a surrounding medium, the substrate being made of a transparent material having a refractive index different from that of the surrounding medium. The smaller a difference in refractive index between the surrounding medium and the substrate, the smaller is reflectivity. Alternatively, the outer reflecting mirror 103 may be, e.g., a metallic film or a DBR (Distributed Bragg Reflector), which is commonly used as a reflecting mirror.

When the reflectivity of the outer reflecting mirror 103 is low, the intensity of light reflected from the outer reflecting mirror 103 is weak, and an amount of light returned to the active layer 105 is reduced. Therefore, noise generated with the light returned to the surface emitting laser is reduced, and an increase of noise in relative intensity of a laser beam itself can be suppressed. Accordingly, an increase of noise in the entirety of an SS-OCT apparatus can also be suppressed.

The reflectivity of the outer reflecting mirror 103 is desirably set to be 10% or less.

When the reflectivity of the outer reflecting mirror 103 is high, a wavelength characteristic of the optical output from the Fabry-Perot etalon side is sharpened, and accuracy in extracting the k-clock signal can be increased.

Injection of carriers to the active layer 105 of the wavelength-variable surface emitting laser can be performed by an optical excitation method of exciting the active layer with light, or a current-applying excitation method of electrically exciting the active layer through an electrode formed on a semiconductor.

In the present invention, any of the above-described excitation methods may be used insofar as the carriers can be injected to such an extent that laser oscillation is developed by the cavity formed by the upper and lower reflecting mirrors 101 and 102.

The movable upper reflecting mirror 101 may be supported on a driving mechanism that is made of, e.g., a miniature structure called MEMS (Micro Electro Mechanical System), and that can be driven electrically and magnetically.

Alternatively, the upper reflecting mirror 101 may be fixed to a piezoelectric material or the like such that it can be driven in a minute amount.

Furthermore, the wavelength-variable surface emitting laser may be constituted by filling the above-mentioned air gap with a member, of which refractive index is changeable by some implement, instead of air such that an effective optical path length of the cavity sandwiched between the upper reflecting mirror 101 and the lower reflecting mirror 102 can be changed.

Thus, the wavelength-variable surface emitting laser may be of any type that includes the implement capable of changing the effective cavity length as described above.

The upper reflecting mirror 101 used here may be a generally-known DBR (Distributed Bragg Reflector) in the form of a multilayer film that is obtained by alternately stacking materials having different refractive indices.

Alternatively, the reflecting mirror may have a structure having a periodic refractive-index distribution formed in the planar direction and realizing a high reflectively, as disclosed in NPL 2.

A surface emitting laser using the reflecting mirror, disclosed in NPL 2, has been studied in recent years (see NPL 3).

The active layer 105 formed on the substrate 107 may be made of a material emitting light in a wavelength band that is useful in an OCT apparatus.

In the OCT apparatus used in ophthalmologic care, for example, a wavelength band where absorption of light by water is small is used because a large amount of water is contained in the vitreous body of an eyeball, etc.

More specifically, a wavelength band of 780 to 920 nm and a wavelength band of 980 to 1120 nm is frequently used. In an OCT apparatus using an endoscope, a wavelength band of 1300 nm is frequently used because light in such a wavelength band is scattered to a less extent by biological tissues and is capable of entering a deeper portion.

An OCT apparatus for industrial uses is employed in, e.g., inspection of semiconductor chips and paintings, and a wavelength band suitable for an inspection target is used. Practical examples of materials of the active layer 105 include AlGaAs, InGaAs, GaInAsP, and GaInNAs.

The lower reflecting mirror 102 formed on the substrate 107 may be a DBR similarly to the upper reflecting mirror 101. In many cases, a surface emitting laser is fabricated by employing the DBR as a reflecting mirror for the reason that the DBR can be formed by alternately developing crystal growth of materials, which have different compositions from each other, on a semiconductor substrate. In some fabrication method, the lower reflecting mirror 102 may be formed by vacuum vapor deposition, for example, in a region of a light emitting unit where a substrate is removed.

Alternatively, the reflecting mirror disclosed in the above-cited NPL 2 may be formed and utilized as the lower reflecting mirror 102.

A laser beam generated with the laser oscillation is usually output from the upper reflecting mirror side in many cases.

Therefore, the reflectivity of the lower reflecting mirror 102 is designed to be as high as possible so that light is output from only the one reflecting mirror side.

In the embodiment of the present invention, however, the laser beam used in the k-clock needs to be taken out from the lower reflecting mirror side. Accordingly, setting the reflectivity of the lower reflecting mirror 102 as close as possible to 100% is not desirable because an optical output is extremely reduced.

In other words, it is desirable that the reflectivity of the lower reflecting mirror 102 is set to such a level at which the laser beam output from the lower reflecting mirror side can be received by the light receiving element without being buried in noise.

In order that the laser beam of the wavelength-variable surface emitting laser is taken out from the lower reflecting mirror side, the substrate needs to be partly removed to form a light taking-out window when the support substrate of the lower reflecting mirror 102 is not transparent to the laser beam.

An SS-OCT apparatus will be described below.

In the SS-OCT apparatus, as described above, a tomographic image is formed through the Fourier transform of an interference signal in a wide wavelength (optical frequency) band.

Therefore, the depth axial image resolution and the depth image-capturing range of an object of which image is to be captured by the SS-OCT apparatus also undergo restrictions attributable to the Fourier transform.

In more detail, the depth image-capturing range is restricted by the sampling optical frequency interval of the interference signal, and the depth axial image resolution is restricted by the optical frequency band subjected to the Fourier transform.

Thus, the optical frequency interval of the k-clock signal formed by the above-described Fabry-Perot etalon also needs to be set to an appropriate optical frequency interval depending on the depth image-capturing range that is required for the SS-OCT apparatus.

Furthermore, the optical distance between the outer reflecting mirror 103 and the lower reflecting mirror 102 needs to be set so as to obtain the optical frequency interval appropriate for the SS-OCT apparatus.

Given that the depth image-capturing range is denoted by X (m) and the velocity of light is denoted by c (m/s), the optical frequency interval is expressed by c/4X (Hz).

For example, when the depth image-capturing range of 10 mm in terms of optical path length is required, the optical frequency interval of 7.5 GHz is required. Since the optical frequency interval required from the depth image-capturing range and the above-described formula to derive the FSR in the Fabry-Perot etalon are the same, it is understood that an optical path length between the reflecting mirrors of the Fabry-Perot etalon just needs to be the same as that of the depth image-capturing range required in a tomographic system.

Given that the optical frequency range for use in forming a tomographic image is Nu and the velocity of light is c, the depth axial image resolution required in the SS-OCT apparatus is expressed by c/2(Nu). For example, when the tomographic image is formed in a wavelength range of 800 to 900 nm, a frequency range of 41.6 THz is resulted because of (Nu)₈₀₀ₙₘ=c/800 nm˜374.7 THz and (Nu)₉₀₀ₙₘ˜333.1 THz, and the depth axial image resolution is about 3.6 micrometers.

In the wavelength-variable surface emitting laser according to this embodiment, the k-clock having the optical path length set to a desired value can be formed easily.

The optical path length can be set just by joining the outer reflecting mirror 103 to the substrate 107 with intervention of a spacer having a predetermined thickness therebetween.

Alternatively, a reflecting surface may be formed on one side of an additional substrate that is transparent to the laser beam, and the transparent substrate may be joined at the side opposite to the reflecting surface to the substrate 107 such that an optical path length corresponding to the thickness of the additional substrate is set. Thus, the frequency interval of the k-clock signal can be set to a desired value just by selecting and joining the spacer or the transparent substrate, which has a thickness suitable for the tomographic system.

The formulae for calculating the depth axial image resolution and the depth image-capturing range, described above, are both restricted by the Fourier transform.

In the actual SS-OCT apparatus, the depth axial image resolution and the depth image-capturing range are further restricted by not only the wavelength band and the spectrum shape, but also the instantaneous spectrum line width (coherence length) of the wavelength-variable surface emitting laser.

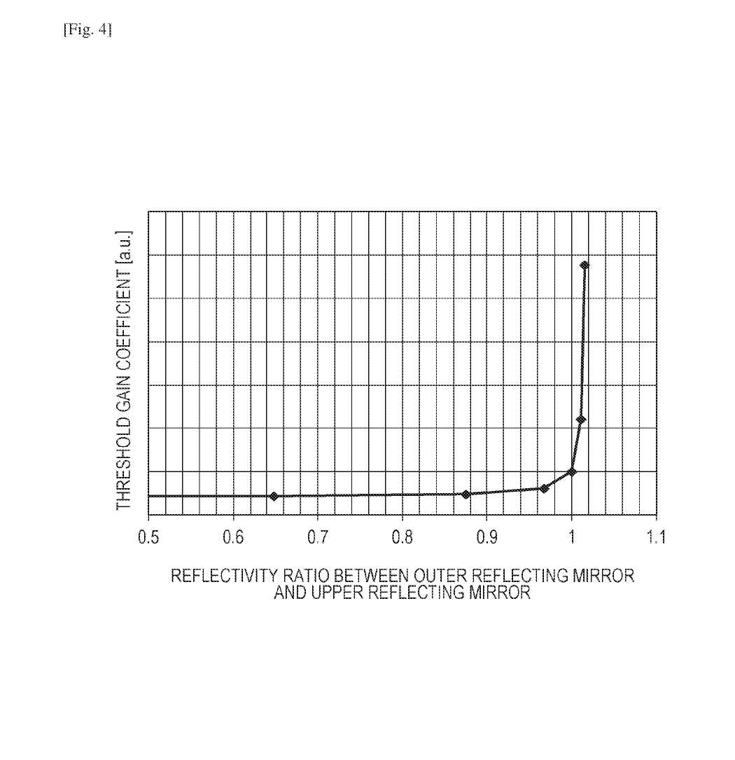

Given that the reflectivity of the outer reflecting mirror 103 used in the Fabry-Perot etalon is denoted by R2, and the reflectivity of the upper reflecting mirror 101 is denoted by R1, the relationship of R1>R2 is preferably satisfied. The reason is that, as illustrated in FIG. 4, when the reflectivity of the upper reflecting mirror 101 and the reflectivity of the outer reflecting mirror 103 become equal to each other, the threshold gain coefficient of the wavelength-variable surface emitting laser is abruptly increased, thus causing degradation in characteristics of the surface emitting laser.

### EXAMPLES

EXAMPLES of the present invention will be described below.

### Example 1

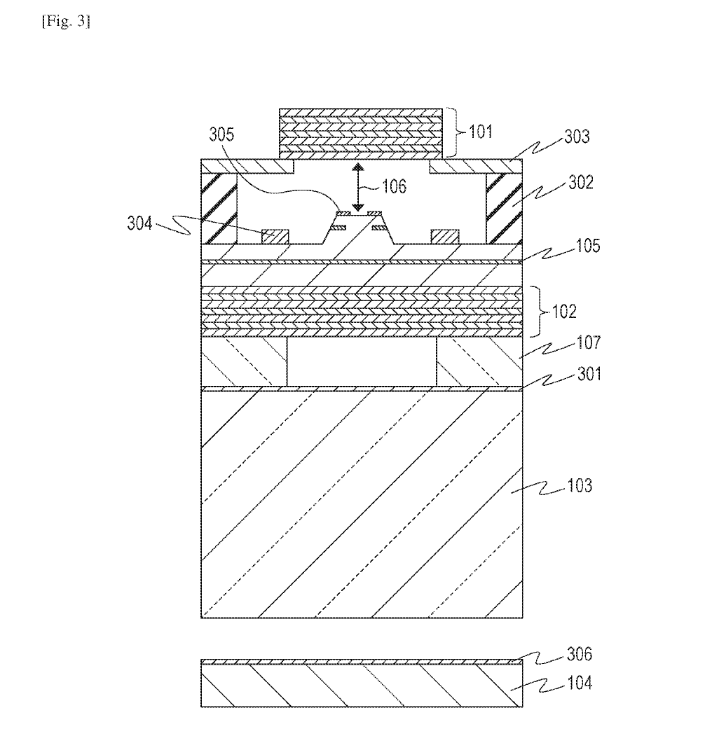

An example of structure of a wavelength-variable surface emitting laser to which the present invention is applied is described, as Example 1, with reference to FIGS. 1 and 3.

In the wavelength-variable surface emitting laser of EXAMPLE 1, as illustrated in FIG. 3, the lower reflecting mirror 102 is formed by stacking 29 pairs of n-type GaAs/AlAs-DBRs having a center wavelength of 1050 nm on a GaAs substrate.

On the lower reflecting mirror 102, there are successively formed n-type Al0.4GaAs of 74.6 nm as a cladding layer, undoped GaAs of 50 nm as a spacer layer, GaAs of 10 nm/InGaAs of 8 nm forming barrier layer/quantum well layer, respectively, which serve as the active layer 105, undoped GaAs of 50 nm as a spacer layer, and p-type Al0.4GaAs of 74.6 nm as a cladding layer.

On the above-mentioned layers, there are further successively formed a selective oxide layer, which is made of p-type Al0.98GaAs of 30 nm and which forms a current confinement structure with selective oxidation, and p-type Al0.4GaAs of 364.6 nm as a cladding layer.

The current confinement structure is formed by etching a wafer of the above-mentioned layer structure down to a lower surface of the selective oxide layer to provide a mesa-shaped portion, and oxidizing the selective oxide layer with wet oxidation.

Thereafter, an insulating film and an electrode 305 having a window serving as a light exit opening are formed as in a general VCSEL (Vertical Cavity Surface Emitting Laser).

In addition. SiO₂ serving as a support member 302 around the mesa-shaped portion is formed, and amorphous Si serving as a resilient deformable support member 303 supported by the support member 302 is formed in the shape of a beam.

Five pairs of AlOx/GaAs-DBRs are supported as the upper reflecting mirror 101 by the resilient deformable support member 303.

The resilient deformable support member 303 is flexed by an electrostatic attraction force generated upon application of a voltage between the resilient deformable support member 303 and a driving electrode 304. With the flexing of the resilient deformable support member 303, the upper reflecting mirror 101 comes closer to the mesa-shaped portion, whereby the air gap is changed.

The surface emitting laser is thus formed in which wavelength is variable with the above-described structure.

The outer reflecting mirror 103 is arranged on the side opposite to the lower reflecting mirror 102 with the GaAs substrate of the above-described surface emitting laser interposed therebetween.

In this EXAMPLE, a quartz glass substrate having a refractive index of about 1.45 is used as the outer reflecting mirror 103 that is the feature of the present invention.

A reflecting surface of the outer reflecting mirror 103 is given by the interface between quartz glass and air. Because a difference in refractive index at the interface between quartz glass and air is small, the interface has a reflectivity of about 3.5% at a wavelength of 1050 nm.

Moreover, because of having a finite thickness, the quartz glass has, in addition to the above-mentioned interface, the other interface at which there also occurs reflection of light. It is hence required to form an anti-reflection film 301 at the other interface.

When the anti-reflection film 301 is formed in a well-known simple sing-layer structure, it can be formed as a film having a refractive index of desirably about 1.2 in an optical thickness of ¼ of the wavelength on condition that the refractive index of air is 1 and the refractive index of the quartz glass is 1.45.

The anti-reflection film 301 may be formed by a plurality of films by employing a general multilayer design technique. As an alternative, the anti-reflection film may be constituted in a way to moderately change the effective refractive index at the interface by employing a structure that is sufficiently smaller than the wavelength, called the Sub Wavelength Structure (SWS). In other words, any type of technique can be used insofar as reflection at the glass-air interface is prevented.

As a result, only one reflecting surface acts as the outer reflecting mirror 103. The Fabry-Perot etalon is constituted between the one reflecting surface and the lower reflecting mirror 102.

The distance between the pair of reflecting mirrors of the Fabry-Perot etalon needs to be determined depending on specifications that are to be achieved with the SS-OCT apparatus.

Furthermore, in the SS-OCT apparatus, because a tomographic image is constructed from a detected signal through the Fourier transform (inverse transform), processing is desirably executed through the FFT (Fast Fourier Transform) capable of performing a high-speed signal processing. Thus, the number of samplings of the object for the signal processing needs to be the N-th power of 2.

On condition that the depth image-capturing range of 10 mm and the depth axial image resolution of 6 micrometers are demanded as the OCT apparatus, the distance between the reflecting mirrors of the Fabry-Perot etalon is required to be 20 mm or more in terms of optical path length (i.e., 7.5 GHz or less in terms of optical frequency resolution) similarly to the depth image-capturing range.

In accordance with the demanded depth axial image resolution of 6 micrometers, the optical frequency range for execution of the Fourier transform is 25 THz or more.

Assuming the optical frequency resolution to be 7.5 GHz, the number of samplings is 3333 in the range of 25 THz.

When the number of samplings is set to the 12-th power of 2, i.e., 4096, it is necessary to compensate for deficient 763 points by zero padding, and to widen a calculation range in the Fourier transform.

An upper limit of the distance between the reflecting mirrors of the Fabry-Perot etalon is determined depending on the number of samplings. Thus, when the number of samplings is set to the 12-th power of 2, i.e., 4096, a limit of the optical frequency resolution is 6.1 GHz resulting from 25 THz/4096 points.

If the sampling is performed at an optical frequency resolution higher than the above-mentioned limit, the optical frequency range for execution of the calculation would be narrower than 25 THz from the restriction of the number of samplings being 4096. Accordingly, the depth axial image resolution would deteriorate to such an extent as not satisfying the demand for the OCT apparatus.

For the reason, the distance between the reflecting mirrors of the Fabry-Perot etalon is desired to be in the range of 10 mm or more in terms of optical path length (i.e., 7.5 GHz or less in terms of optical frequency resolution) and 24.6 mm or less in terms of optical path length (i.e., 6.1 GHz or more in terms of optical frequency resolution) in this EXAMPLE.

In this EXAMPLE, the quartz glass substrate is used as the outer reflecting mirror 103. The anti-reflection film is formed at one interface of the quartz glass substrate, and the other interface thereof is utilized as the reflecting surface.

The case of joining the quartz glass substrate to the GaAs substrate is considered here. The resonant wavelength range of the wavelength-variable surface emitting laser according to this EXAMPLE is about 1000 nm to 1100 nm, and the GaAs substrate is a transparent material in such a wavelength band.

In the wavelength-variable surface emitting laser of this EXAMPLE, therefore, the laser beam is transmissible through the substrate and can be taken out from the rear surface of the substrate.

The surface of the outer reflecting mirror 103 where the anti-reflection film 301 is formed and the rear surface of the GaAs substrate are joined to each other in parallel.

The distance between the reflecting mirrors of the Fabry-Perot etalon is determined, in terms of optical path length, from 625 micrometers of the GaAs substrate having the refractive index of 3.65 and the thickness of the quartz glass substrate having the refractive index of 1.45.

It is hence understood that the quartz glass substrate having the thickness of 15.4 mm is to be used to obtain the required optical path length of 24.6 mm.

An anti-reflection film is desirably formed on the rear surface of the GaAs substrate as well similarly to the above-described anti-reflection film formed on the quartz glass substrate.

The Fabry-Perot etalon sharing the lower reflecting mirror 102 of the wavelength-variable surface emitting laser can be formed as described above.

A photodiode serving as the light receiving element 104 is arranged outside the outer reflecting mirror 103. An anti-reflection film 306 is formed on a surface of the photodiode 104 on the side closer to the outer reflecting mirror 103.

The photodiode monitors the intensity of the laser beam output from the wavelength-variable surface emitting laser through the Fabry-Perot etalon.

The intensity of a monitored signal is modulated depending on the optical frequency interval of the FSR in the Fabry-Perot etalon.

An interference signal at a uniform optical frequency interval can be obtained by detecting a peak of the light intensity at the interval of 6.1 GHz, and by sampling the intensity of the OCT interference signal with timing of the detection being a trigger.

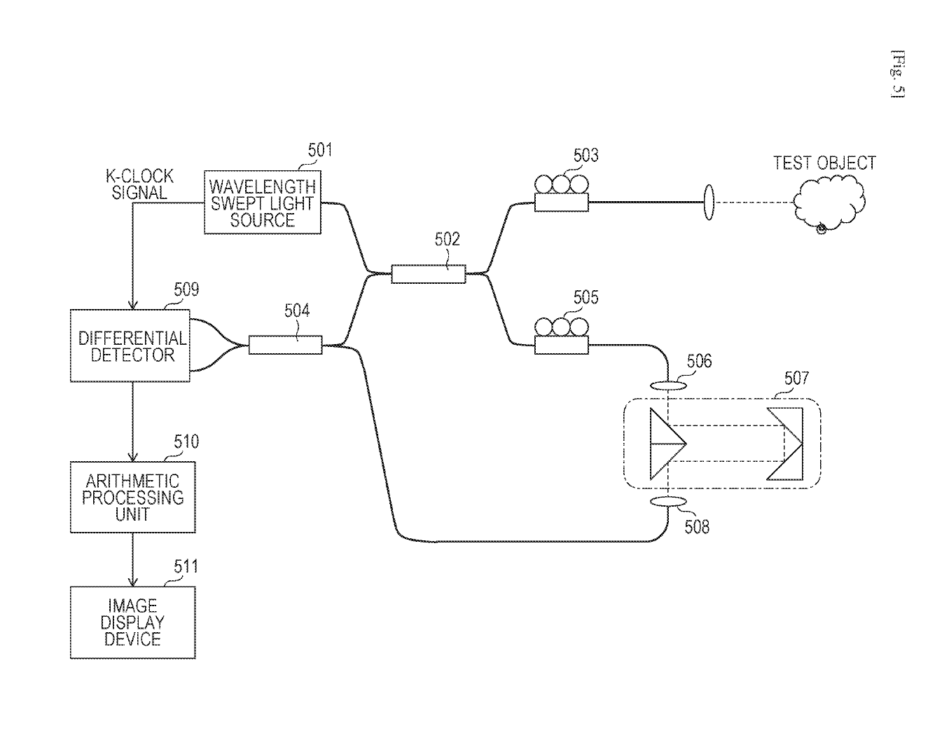

The SS-OCT apparatus using the wavelength-variable surface emitting laser, which outputs the k-clock signal in such a manner, will be described below with reference to FIG. 5.

The wavelength-variable surface emitting laser according to the present invention is used as a wavelength swept light source 501. A laser beam output from the wavelength swept light source 501 and having a wavelength changed over time passes through a fiber coupler 502 that branches the laser beam into two beams. One laser beam is applied to a test object through a lens. The other laser beam passes through a collimator lens 506 and enters an optical path length adjustment mechanism 507. Thereafter, the other laser beam is condensed to a fiber coupler through a collimator lens 508.

Reflected light from the test object is also collected to a fiber coupler through a test-object optical path through which the reflected light from the test object is transferred. In other words, the reflected light from the test object passes through the lens again for return to the fiber coupler 502 and is guided to a fiber coupler 504 through the fiber coupler 502.

Furthermore, the other laser beam is collected to the fiber coupler along a reference-light optical path after being transferred through the optical path length adjustment mechanism. In other words, reference light having passed through the optical path length adjustment mechanism 507 is also collected to the fiber coupler 504.

Signal light from the test object and the reference light having passed through the optical path length adjustment mechanism 507 are combined with each other in the fiber coupler (interference portion) 504, thus generating an interference signal (interference light). The interference signal is branched into two parts by the fiber coupler 504, and only an interference component is detected as the interference signal by a differential detector (optical detector) 509 with a high S/N ratio.

From the interference signal generated from the differential detector 509, the desired interference signal is obtained in synchronism with a k-clock signal (trigger signal) output from the wavelength-variable surface emitting laser according to the present invention.

The obtained interference signal is processed in an arithmetic processing unit 510 through the Fourier transform executed on interference spectrum data at the uniform optical frequency interval, and the arithmetic processing unit 510 obtains depth information of the test object. The obtained depth information is displayed as a tomographic image by an image display device 511.

### Example 2

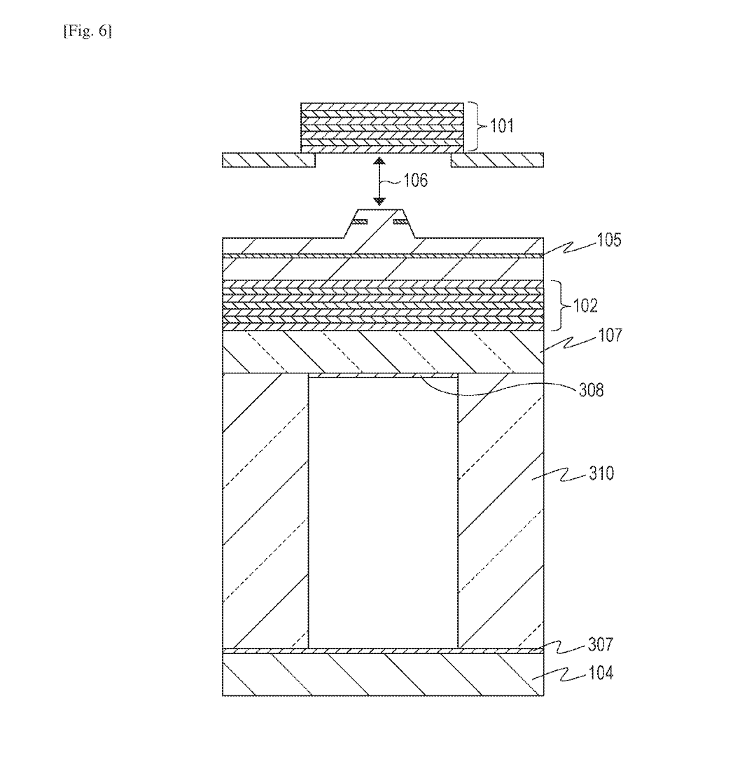

An example of structure in which the light receiving element 104 to receive an optical output for the k-clock and a reflecting mirror 307 are integrated with each other will be described below as EXAMPLE 2 with reference to FIG. 6.

While a wavelength-variable surface emitting laser of EXAMPLE 2 has a similar basic structure to that of EXAMPLE 1, EXAMPLE 2 is featured in that the reflecting mirror 307 constituting the Fabry-Perot etalon is formed on a surface of the light receiving element 104.

In this EXAMPLE, because the wavelength-variable surface emitting laser has a wavelength band of 1050 nm, an InGaAs-PIN photodiode is used as the light receiving element 104.

In the photodiode serving as the light receiving element 104 in this EXAMPLE, a reflecting film serving as the reflecting mirror 307 is formed on a surface of the photodiode by stacking two pairs of DBRs made of SiO₂/TiO₂ each having a film thickness of Lambda/4n (where Lambda is 1050 nm and n is the refractive index of each layer).

The substrate 107 is made of a material that is transparent to the resonant wavelength of the surface emitting laser. Therefore, the substrate 107 is not required to have an opening, i.e., a bore, through which light enters the Fabry-Perot etalon. An anti-reflection film 308 is formed on a surface of the substrate 107 on the side closer to the light receiving element 104.

The above-described photodiode including the reflecting film is arranged, instead of the outer reflecting mirror 103 and the light receiving element 104 in EXAMPLE 1, on the side of the substrate 107 opposite to the active layer 105 with the lower reflecting mirror 102 of the wavelength-variable surface emitting laser interposed therebetween. The substrate 107 of the wavelength-variable surface emitting laser and the photodiode including the reflecting film are joined to each other with a spacer 310 interposed therebetween.

The spacer 310 is formed in a shape having a hole in a laser-beam exit portion so that the laser beam output from the lower reflecting mirror side of the wavelength-variable surface emitting laser can pass through the spacer.

With the structure described above, the Fabry-Perot etalon is formed between the lower reflecting mirror and the reflecting film formed on the photodiode.

A thickness of the spacer 310 is selected depending on specifications that are to be achieved with the SS-OCT apparatus. On condition of similar specifications to those in EXAMPLE 1, the thickness of the spacer is set to 24.6 mm such that the optical path length of 24.6 mm providing the FSR of the optical frequency of 6.1 GHz is obtained.

While the spacer 310 having the hole to allow passage of the laser beam therethrough is used here, there are no problems in employing the spacer 310, which does not have the hole, when a substrate made of an optically transparent material is used as the spacer.

In such a case, the thickness of the spacer needs to be determined in consideration of the refractive index of the substrate.

Moreover, if unnecessary reflection occurs at the interface between the spacer and the substrate of the wavelength-variable surface emitting laser, the desired k-clock signal would not be obtained. Accordingly, the reflection at that interface needs to be suppressed, for example, by forming an anti-reflection film at the interface.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-146953, filed Jul. 12, 2013, which is hereby incorporated by reference herein in its entirety.

### REFERENCE SIGNS LIST

101 upper reflecting mirror
102 lower reflecting mirror
103 outer reflecting mirror
104 light receiving element
105 active layer
106 air gap
107 substrate

1. A surface emitting laser comprising:
a first reflecting mirror;
a second reflecting mirror;
an active layer disposed between the first reflecting mirror and the second reflecting mirror;
a third reflecting mirror arranged on an opposite side of the active layer with respect to the second reflecting mirror; and
a light receiving element arranged to receive light passing through the third reflecting mirror,
wherein the surface emitting laser having a resonant wavelength changed with movement of the first reflecting mirror relative to the second reflecting mirror,
wherein the second reflecting mirror and the third reflecting mirror constitute an etalon so that transmittance of the etalon varies at a certain period of an optical frequency within a range of a wavelength emitted by the surface emitting laser.

2. The surface emitting laser according to claim 1, wherein the surface emitting laser constitutes a light source used in an optical coherence tomography apparatus.

3. The surface emitting laser according to claim 2, wherein a Free Spectral Range (FSR) determined depending on an optical distance between the second reflecting mirror and the third reflecting mirror is narrower than a frequency interval expressed by c/4x where x (m) is a predetermined depth image-capturing range in the optical coherence tomography apparatus, and c (m/s) is velocity of light.

4. The surface emitting laser according to claim 2, wherein a Free Spectral Range (FSR) determined depending on an optical distance between the second reflecting mirror and the third reflecting mirror is wider than a frequency interval of c/2Ny resulting from dividing a frequency range, which is expressed by c/2y where y is a predetermined depth axial image resolution in the optical coherence tomography apparatus and c is velocity of light, by a number N of data subjected to Fourier transform in the optical coherence tomography apparatus.

5. The surface emitting laser according to claim 1, wherein a relationship of R1>R2 is satisfied given that R1 is reflectivity of the first reflecting mirror, and R2 is reflectivity of the third reflecting mirror.

6. The surface emitting laser according to claim 1, wherein the third reflecting mirror comprises a substrate transparent to a laser beam output from the surface emitting laser, and
an anti-reflection film for the laser beam is formed on one surface of the substrate.

7. The surface emitting laser according to claim 6, wherein the surface in which the anti-reflection film is formed is a surface of the substrate on side closer to the second reflecting mirror.

8. The surface emitting laser according to claim 1, wherein the third reflecting mirror is formed on a surface of the light receiving element.

9. The surface emitting laser according to claim 1, wherein reflectivity of the third reflecting mirror is 10% or less.

10. The surface emitting laser according to claim 1, wherein an optical distance between the second reflecting mirror and the third reflecting mirror is 20 mm or more and 24.6 mm or less.

11. The surface emitting laser according to claim 1, further comprising a substrate arranged between the second reflecting mirror and the third reflecting mirror to support the second reflecting mirror,
wherein the substrate is bored in a portion corresponding to the active layer.

12. An optical coherence tomography apparatus comprising:
a light source constituted by the surface emitting laser according to claim 1;
a test-object optical path through which light from the light source is applied to a test object and reflected light from the test object is transferred;
a reference-light optical path through which the light from the light source is transferred;
an interference unit configured to interfere the reflected light transferred through the test-object optical path and the light transferred through the reference-light optical path with each other;
an optical detection unit configured to detect interference light from the interference unit and to generate an interference signal; and
an arithmetic processing unit configured to obtain a tomographic image of the test object in accordance with the interference signal that is obtained in synchronism with a trigger signal output from the light source.

13. A surface emitting laser comprising:
a first reflecting mirror;
a second reflecting mirror;
an active layer disposed between the first reflecting mirror and the second reflecting mirror,
a third reflecting mirror arranged on an opposite side of the active layer with respect to the second reflecting mirror; and
a light receiving element arranged to receive light passing through the third reflecting mirror,
wherein the surface emitting laser having a resonant wavelength changed with movement of the first reflecting mirror relative to the second reflecting mirror,
wherein the surface emitting laser constitutes a light source used in an optical coherence tomography apparatus, and
wherein a Free Spectral Range (FSR) determined depending on an optical distance between the second reflecting mirror and the third reflecting mirror is narrower than a frequency interval expressed by c/4x where x (m) is a predetermined depth image-capturing range in the optical coherence tomography apparatus, and c (m/s) is velocity of light.

14. A surface emitting laser comprising:
a first reflecting mirror;
a second reflecting mirror;
an active layer disposed between the first reflecting mirror and the second reflecting mirror,
a third reflecting mirror arranged on an opposite side of the active layer with respect to the second reflecting mirror; and
a light receiving element arranged to receive light passing through the third reflecting mirror,
wherein the surface emitting laser having a resonant wavelength changed with movement of the first reflecting mirror relative to the second reflecting mirror,
wherein the surface emitting laser constitutes a light source used in an optical coherence tomography apparatus, and
wherein a Free Spectral Range (FSR) determined depending on an optical distance between the second reflecting mirror and the third reflecting mirror is wider than a frequency interval of c/2Ny resulting from dividing a frequency range, which is expressed by c/2y where y is a predetermined depth axial image resolution in the optical coherence tomography apparatus and c is velocity of light, by a number N of data subjected to Fourier transform in the optical coherence tomography apparatus.
